(19) United States
(12) Patent Application Publication
(10) Pub. No.: US 2026/0343865 A1
(43) Pub. Date: Oct. 29, 2026

(54) SEMICONDUCTOR STRUCTURE

(71) Applicant: Fujian Jinhua Integrated Circuit Co., Ltd., Fujian (CN)

(72) Inventors: Zhilin LU, Fujian (CN); Zunshi CAI, Fujian (CN); Chaolun FU, Fujian (CN)

(73) Assignee: Fujian Jinhua Integrated Circuit Co., Ltd., Fujian (CN)

(21) Appl. No.: 19/651,766

(22) Filed: Apr. 19, 2026

(30) Foreign Application Priority Data
Apr. 29, 2025 (CN) 202510554525.8

(51) Int. Cl. H10B 12/00

(52) U.S. Cl. CPC H10B 12/488

(57) ABSTRACT

The present application provides a semiconductor structure, applied in the field of semiconductor technology. In the present application, plugs in the semiconductor structure can be bent, and contact pads thereon can have different inclination angles relative to the top surfaces of the plugs, thereby proposing a new structure and improving both the performance and reliability of the semiconductor structure.

### CROSS-REFERENCE TO RELATED APPLICATION

This application claims priority to Chinese Patent Application No. 202510554525.8, filed on Apr. 29, 2025, which is hereby incorporated by reference in its entirety.

### TECHNICAL FIELD

The present application relates to the technical field of semiconductors, in particular to a semiconductor structure.

### BACKGROUND

Dynamic random-access memory (DRAM) belongs to a kind of volatile memory, and includes an array area composed of a plurality of memory cells and a peripheral area composed of a control circuit. Each memory cell is composed of a transistor and a capacitor electrically connected to the transistor, and the transistor controls the storage or release of electric charge in the capacitor to achieve the purpose of data storage. The control circuit can be addressed to each memory cell through a word line (WL) and a bit line (BL) that span the array area and are electrically connected to each memory cell to control the access of data of each memory cell. However, due to the limitation of process technology, the existing dynamic random-access memory still has many defects, which need further improvement to effectively enhance the performance and reliability of related memory devices.

### SUMMARY

The purpose of the present application is to provide a semiconductor structure, to propose a new structure for semiconductor structures, and to improve the reliability and performance of the semiconductor structure.

To solve the above technical problem, the present application provides a semiconductor structure, including:
a substrate;
a plurality of plugs, extending along a first direction and disposed on the substrate spaced apart from each other along a second direction perpendicular to the first direction;
a plurality of contact pads, disposed on the plurality of plugs respectively, where at least one contact pad among the plurality of contact pads has a top surface that is a horizontal plane extending parallel to the second direction, and at least two contact pads among the plurality of contact pads have top surfaces having different inclination angles relative to the horizontal plane.

In one embodiment, at least one plug among the plurality of plugs has a curved side surface, and the side surface has a recess.

In one embodiment, the semiconductor structure may further include:
a plurality of auxiliary lines, each of which is defined by a straight line connecting a topmost point and a bottommost point of the side surface of each of the plugs; a maximum distance in the second direction from the recess of the side surface each of the plugs to the corresponding auxiliary line is a first offset.

In one embodiment, the first offsets between the plurality of plugs and the corresponding auxiliary lines increase from a central position to an edge position.

In one embodiment, the side surface of at least one plug further has a protruding part, and a maximum distance in the second direction from the protruding part to the corresponding auxiliary line is a second offset.

In one embodiment, for the same plug, the first offset is greater than the corresponding second offset.

In one embodiment, the plurality of plugs includes a first plug, a second plug, and a third plug arranged sequentially along the second direction from the central position to the edge position; and the first plug, the second plug, and the third plug physically contact a first contact pad, a second contact pad, and a third contact pad, respectively; where the first offsets and/or the second offsets of the first plug, the second plug, and the third plug progressively increase.

In one embodiment, a top surface of the first contact pad is a horizontal plane extending parallel to the second direction, a top surface of the second contact pad has a first inclination angle relative to the horizontal plane, a top surface of the third contact pad has a second inclination angle relative to the horizontal plane; the second contact pad is located between the first contact pad and the third contact pad, and the first inclination angle is smaller than the second inclination angle.

In one embodiment, the inclination angles of the top surfaces of the multiple contact pads relative to the horizontal plane increase from the central position to the edge position along the second direction.

In one embodiment, a ratio of a height in the first direction to a width in the second direction of the plug is greater than 10.

In one embodiment, the semiconductor structure may further include: dielectric layers between adjacent contact pads and between adjacent plugs.

In one embodiment, the contact pad located at edge position among the plurality of contact pads do not have other plugs provided within the dielectric layer on the side opposite to the other contact pads.

In one embodiment, the semiconductor structure may further include:
a plurality of vertical lines, each of which is defined by a straight line passing through the bottommost point of the side surface of the plug and extending parallel to the first direction; the plug at least includes a first portion and a second portion respectively located at two sides of the corresponding vertical line.

To solve the above problems, the present application further provides a semiconductor structure, including:
a substrate;
a plurality of plugs, extending along a first direction and disposed on the substrate spaced apart from each other along a second direction perpendicular to the first direction;
a plurality of auxiliary lines, each of which is defined by a straight lines connecting a topmost point and a bottommost point of a single side surface of the plug, where the single side surface of at least one plug includes a first portion and a second portion respectively bending toward two opposite sides of the auxiliary line.

In one embodiment, the semiconductor structure may further include:
a plurality of contact pads, disposed on the substrate spaced apart from each other along the second direction, and each contact pad physically contacts each respective plug; where, the contact pad located at an edge position among the plurality of contact pads has an inclination angle relative to a horizontal plane extending along the second direction is greater than inclination angles of other contact pads relative to the horizontal plane.

In one embodiment, the first portion of the single side surface of the plug is located on an upper half of the plug and forms a recessed part, a maximum distance in the second direction from the first portion to the corresponding auxiliary line is a first offset, where the first offsets between the plurality of plugs and the corresponding auxiliary lines increase from a central position to an edge position.

In one embodiment, the second portion of the single side surface of the plug is located on a lower half of the plug and forms a protruding part, and a maximum distance in the second direction from the second portion to the corresponding auxiliary line is a second offset.

In one embodiment, for the same plug, the first offset is greater than the corresponding second offset.

In one embodiment, the inclination angles of the top surfaces of the plurality of contact pads relative to the horizontal plane increase from the central position to the edge position.

In one embodiment, a ratio of a height in the first direction to a width in the second direction of the plug is greater than 10.

In the present application, the semiconductor structure includes a plurality of plugs and a plurality of contact pads, where the plurality of contact pads are respectively disposed on the plurality of plugs, and at least one contact pad has a top surface that is a horizontal plane extending parallel to the first direction, and top surfaces of at least two contact pads to have different inclination angles relative to the horizontal plane, thereby proposing a new structure for semiconductor structures, and achieving the purpose of improving both the performance and reliability of semiconductor devices.

### BRIEF DESCRIPTION OF DRAWINGS

The drawings are provided for further understanding of the present application, constitute a part of the specification, and are used together with the following specific embodiments to explain the present application, but do not limit the present application. Among the drawings:

FIG. 1 is a schematic diagram of a semiconductor structure in a first embodiment of the present application.

FIG. 2 is a schematic diagram of an enlarged semiconductor structure corresponding to the black dashed box in FIG. 1 with auxiliary lines added in an embodiment of the present application.

FIG. 3 is a schematic diagram of a semiconductor structure in a second embodiment of the present application.

FIG. 4 is a schematic diagram of an enlarged semiconductor structure corresponding to the black dashed box in FIG. 3 with auxiliary lines added in an embodiment of the present application.

Where, the reference signs are:

100-substrate, R1-first area, R2-second area, R3-third area, 110-first dielectric layer, 120-plugs (first-layer plugs), 121-first plug, 122-second plug, 123-third plug, 130-second dielectric layer, 140-contact pads, 141-first contact pad, 142-second contact pad, 143-third contact pad, 150-third dielectric layer, 160-next-layer plugs (second-layer plugs), 170-fourth dielectric layer, 141HP-horizontal plane (angle between the first contact pad and the first direction, 0), ∠1-first inclination angle (between the first contact pad and the horizontal plane, 0), ∠2-second inclination angle (between the second contact pad and horizontal plane, greater than 0), ∠3-third inclination angle (between the third contact pad and horizontal plane, greater than 0 and greater than the second inclination angle), AL-auxiliary line, VL-vertical line, W1-first offset, W2-second offset.

In the drawings, the same reference signs are used for the same components, and the drawings are not drawn to actual scale.

### DESCRIPTION OF EMBODIMENTS

To make the technical solutions and advantages of the embodiments of the present application clearer, the technical solutions of the present application will be described in further detail below with reference to the drawings and embodiments. Although exemplary embodiments of the present application are shown in the drawings, it should be understood that the present application may be implemented in various forms and should not be limited by the embodiments described herein. On the contrary, these embodiments are provided to enable a more thorough understanding of the present application and to fully convey the scope of the present application to those skilled in the art.

The present application is described more specifically by examples with reference to the drawings in the following paragraphs. The advantages and features of the present application will become clearer from the following description and the claims. It should be noted that all drawings adopt a very simplified form and use non-precise scales, merely are used for facilitating and clearly assisting in explaining the purpose of the embodiments of the present application. It should be understood that the meanings of “on”, “over”, and “above” in the present application should be interpreted in the broadest sense, so that “on” not only means directly “on” something without intervening features or layers (i.e., directly on something), but also includes the meaning of being “on” something with intervening features or layers therebetween.

Furthermore, for the convenience of description, spatial relative terms such as “on”, “over”, “above”, “upper”, and “upper part” may be used herein to describe the relationship of one element or feature to another element or feature as illustrated in the drawings. In addition to the orientation depicted in the drawings, spatial relative terms are intended to encompass different orientations of the device during use or operation. The device may be oriented in other ways (rotated 90 degrees or in other orientations) and the spatial relative descriptors used herein may be interpreted accordingly.

In the embodiments of the present application, terms such as “first”, “second”, etc., are used to distinguish similar objects and are not necessarily used to describe a specific sequence or order. It should be noted that the technical solutions recorded in the embodiments of the present application can be combined arbitrarily when they do not conflict.

For ease of understanding, a first direction, a second direction, and a horizontal plane are defined below, where the first direction is perpendicular to a surface of a substrate 100, corresponding to D1 in the drawings; the second direction is parallel to the surface of the substrate 100, corresponding to D2 in the drawings; and the horizontal plane is a top surface of a contact pad 140 extending parallel to the second direction, corresponding to 141HP in the drawings, and the first direction D1 and the second direction D2 are perpendicular to each other.

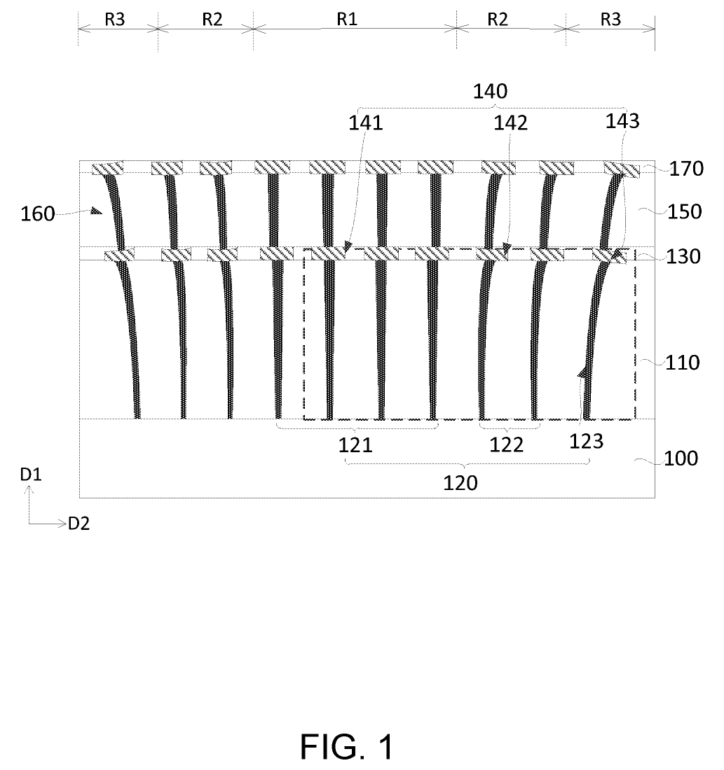

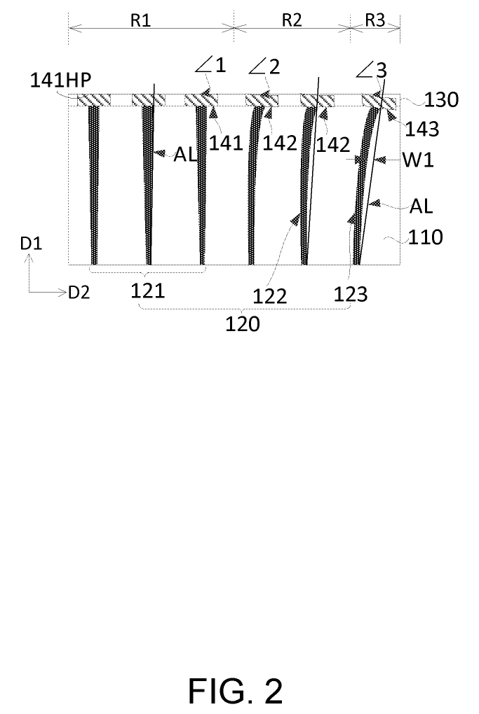

Please refer to FIGS. 1 and 2. FIG. 1 is a schematic cross-sectional view of a portion of a semiconductor structure in a first embodiment of the present application. FIG. 2 is a schematic diagram of an enlarged semiconductor structure corresponding to the black dashed box in FIG. 1 with auxiliary lines added. The semiconductor structure of the present application can be used in manufacturing dynamic random-access memory (DRAM). Without departing from the spirit of the present application, the present application can also be applied to other types of memory. As shown in FIGS. 1 and 2, a semiconductor structure in the first embodiment of the present application includes a substrate 100, a plurality of plugs 120, and a plurality of contact pads 140. Where the substrate 100 can be divided into at least one first area R1, a plurality of second areas R2, and a plurality of third areas R3 arranged along the second direction D2 according to the difference in inclination angles between the top surfaces of the contact pads 140 and the horizontal plane 141HP. The first area R1 can be located in a middle region of the substrate 100, the plurality of second areas R2 can be located in partial regions of the substrate 100 at two sides of the first area R1, and the plurality of third areas R3 can be located in partial regions of the substrate 100 at two sides of the second areas R2. In this way, in the second direction D2, observing from the first area R1 from left to right or right to left, the substrate 100 includes sequentially adjacent first area R1, second area R2, and third area R3, but is not limited thereto. A first dielectric layer 110 may further be disposed on the substrate 100. A thickness of the first dielectric layer 110 in the first direction D1 is greater than or equal to an extension length of the plurality of plugs 120 in the first direction D1, so that the plurality of plugs 120 are all wrapped by the first dielectric layer 110 to achieve the effect of insulating different plugs 120. Exemplarily, the substrate 100 is any suitable substrate material known in the field, for example, it can be a silicon substrate, a silicon-containing substrate, a silicon-on-insulator substrate, or a substrate formed by other suitable materials, but is not limited thereto. The material of the first dielectric layer 110 may include silicon oxide (SiO₂), silicon nitride (SiN), silicon oxynitride (SiON), silicon carbonitride (SiCN), nitrogen-doped silicon carbide (NDC), low-k dielectric materials such as fluorinated silica glass (FSG), carbon-silicon oxide (SiCOH), spin-on glass, a porous low-k dielectric material, an organic polymer dielectric material, or a combination of the above materials, but is not limited thereto.

The plurality of plugs 120 can be disposed in different dielectric layers of the substrate 100 along the first direction D1, for example, disposed in the first dielectric layer 110 and disposed in a third dielectric layer 150, and the plurality of plugs 120 located in different dielectric layers can also be arranged spaced apart from each other along the second direction D2 in different areas of the substrate 100, i.e., in the first area R1, second area R2, and third area R3, and the number of plugs 120 in different dielectric layers in different areas can be the same or different. Exemplarily, in the embodiment, the plugs 120 located in the first dielectric layer 110 are referred to as first-layer plugs, and the plugs 120 located in the third dielectric layer 150 are referred to as second-layer plugs 160. The following description will take a plurality of plugs 120 located in the first dielectric layer 110 (first-layer plugs) as an example to introduce characteristics such as position and connection relationship of the plurality of plugs 120 within the same dielectric layer. Those skilled in the art can easily understand related characteristics of a plurality of plugs 120 located in other dielectric layers, such as the third dielectric layer 150, based on the above introduction of the plurality of plugs 120 in the first dielectric layer 110.

Specifically, each of side surfaces of some plugs 120 among the plurality of plugs 120 is not curved and has no recess, such as the plugs marked with reference numeral “121” in FIGS. 1 or 2. Each of side surfaces of some plugs 120 may be curved along the second direction D2 and has a recess, such as the plugs marked with reference numerals “122 or 123” in FIGS. 1 or 2, and these plugs 120 with curved side surfaces and recesses have different degrees of curvature along the second direction D2. For the convenience of description, in the embodiment, the plurality of plugs 120 are divided into first plugs 121, second plugs 122, and third plugs 123, and a first offset from the recess of the side surface of each plug 120 to a corresponding auxiliary line along the second direction D2 is used to identify the degree of curvature of each of the first plugs 121, the second plugs 122, and the third plugs 123. Where, the auxiliary line is a straight line connecting a topmost point and a bottommost point of the side surface of each of the plurality of plugs 120, such as the straight line marked with reference numeral “AL” in FIG. 2; the first offset is the maximum distance in the second direction D2 from the recess of the side surface of each plug 120 to the corresponding auxiliary line, such as the distance marked with reference numeral “W1” in FIG. 2, but is not limited thereto. Exemplarily, the material of the plug 120 can be metallic tungsten, and a ratio of its height in the first direction D1 to its width in the second direction D2 can be greater than 10, i.e., it is strip-shaped, but is not limited thereto. In the embodiment, the first plugs 121 can be disposed in the first dielectric layer 110 of the first area R1, the second plugs 122 can be disposed in the first dielectric layer 110 of the second area R2, and the third plugs 123 can be disposed in the first dielectric layer 110 of the third area R3. Under this arrangement, the first offsets W1 from the first plugs 121 to the third plugs 123 (from a central position to an edge position) increase from the first area R1 to the third area R3, i.e., the first offsets W1 of the first plugs 121 are less than the first offsets W1 of the second plugs 122, and the first offsets W1 of the second plugs 122 are less than the first offsets W1 of the third plugs 123.

It should be understood that, considering the position of the recess of the side surface (also called single side surface) of each plug 120 at the left or right side of the corresponding auxiliary line AL, or considering the bending position of the recess toward the corresponding auxiliary line AL, the first offset W1 of the plug 120 can also be understood or referred to as a first portion or a recess part of the single side surface of the plug 120. Obviously, the first portion or recess part is located on the upper half of the corresponding plug 120, so that the corresponding plug 120 is C-shaped.

Furthermore, a second dielectric layer 130 is disposed on the first dielectric layer 110 in which the plurality of plugs 120 are formed. The material of the second dielectric layer 130 can be the same as that of the first dielectric layer 110, for example, both are silicon oxide. The plurality of contact pads 140 can be disposed spaced apart from each other along the second direction D2 within the second dielectric layer 130, and the bottoms of the plurality of contact pads 140 physically contact the plugs 120 respectively. Based on the division method of the plugs 120, in this embodiment the contact pads 140, which are disposed on and physically connected to the first plugs 121, the second plugs 122, and the third plugs 123 respectively, are divided into first contact pads 141, second contact pads 142, and third contact pads 143. Among the plurality of contact pads 140, at a side, facing away from other contact pads (the second contact pads 142 or the first contact pads 141), of a contact pad (i.e., the third contact pad 143) located at an edge position, no other contact pads 140 are disposed in the second dielectric layer 130 and no corresponding plugs 120 are disposed in the first dielectric layer 110. It should be understood that the top surfaces of the first plugs 121, the second plugs 122, and the third plugs 123 would form different angles with the horizontal plane 141HP due to the different degrees of curvature of their side surfaces, thereby causing the top surfaces of the respective contact pads 140 conformally formed on and physically contacting the top surfaces of the plugs to have different inclination angles relative to the horizontal plane 141HP. In one embodiment, for the plurality of contact pads 140, the inclination angles of the top surfaces relative to the horizontal plane 141HP increase from a central position to an edge position along the second direction D2 (e.g., from the first area R1 to the third area R3). For example, as shown in FIG. 2, the top surface of the first contact pad 141 is parallel to the horizontal plane 141HP, i.e., the first inclination angle ∠1 relative to the horizontal plane 141HP is 0, and is less than a second inclination angle ∠2 of the top surface of the second contact pad 142 relative to the horizontal plane 141HP; the second inclination angle ∠2 of the top surface of the second contact pad 142 relative to the horizontal plane 141HP is less than a third inclination angle ∠3 of the top surface of the third contact pad 143 relative to the horizontal plane 141HP, i.e., 0=∠1<∠ 2<∠3, but is not limited thereto. Exemplarily, the material of the contact pad 140 can be a conductive material, such as a metal conductive material or a non-metal conductive material such as aluminum, titanium, tantalum, tungsten, copper, titanium nitride, titanium carbide, tantalum nitride, titanium-tungsten, titanium nitride, polysilicon, doped silicon, metal silicide, or any combination thereof, but is not limited thereto.

In addition, a third dielectric layer 150 and a fourth dielectric layer 170 are sequentially disposed from bottom to top above the second dielectric layer 130 in the embodiment. The materials of the third dielectric layer 150 and the fourth dielectric layer 170 can be the same as that of the first dielectric layer 110, such as silicon oxide. Moreover, the interiors of the third dielectric layer 150 and fourth dielectric layer 170 may be similar to that of the first dielectric layer 110 and second dielectric layer 130, which are provided with corresponding first plugs 121, second plugs 122, third plugs 123, and first contact pads 141, second contact pads 142, and third contact pads 143 that are in physical contact with them. Where, the bottoms of the first plugs 121, the second plugs 122, and the third plugs 123 located in the third dielectric layer 150 should also be physical contact with the first contact pads 141, the second contact pads 142, and the third contact pads 143 located below and aligned with them, respectively.

It should be understood that “conformally” in the present application refers to constructing a continuous structural shape by using the similarity and correlation in morphology between two or more shapes.

Those skilled in the art of the present application should readily understand that, to meet the requirements of actual products, the semiconductor structure of the present application may also have other patterns and is not limited to the above. Other embodiments or variations of the semiconductor structure of the present application will be further described below. To simplify the description, the following description focuses on the differences between the embodiments, and the same parts will not be repeated. Furthermore, identical components in the various embodiments of the present application are labeled with identical reference signs to facilitate cross-referencing between the embodiments.

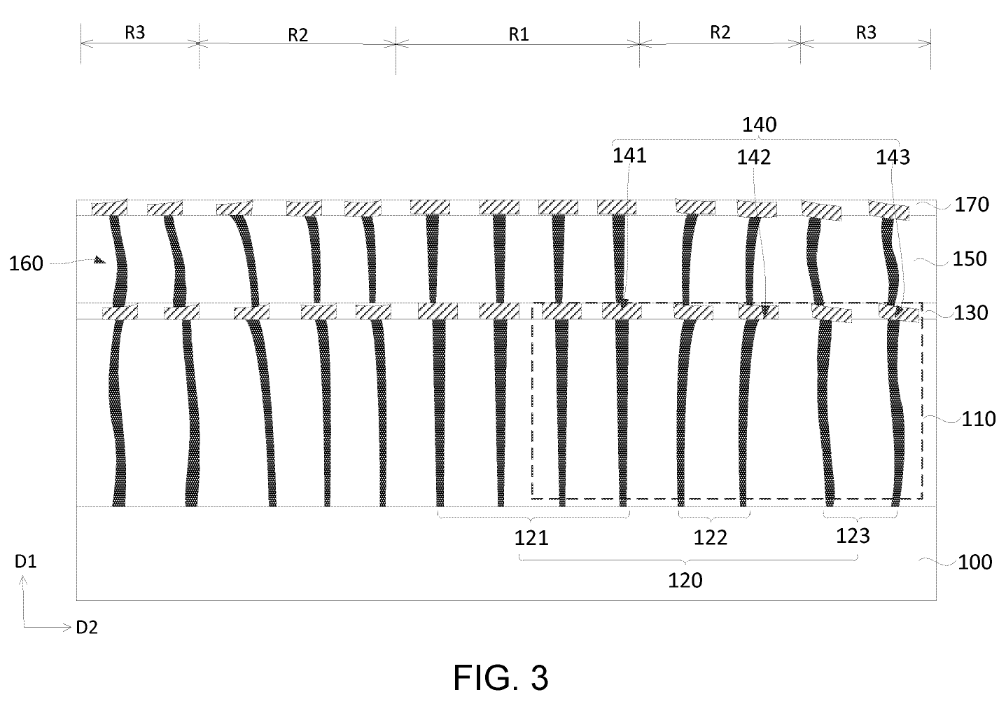

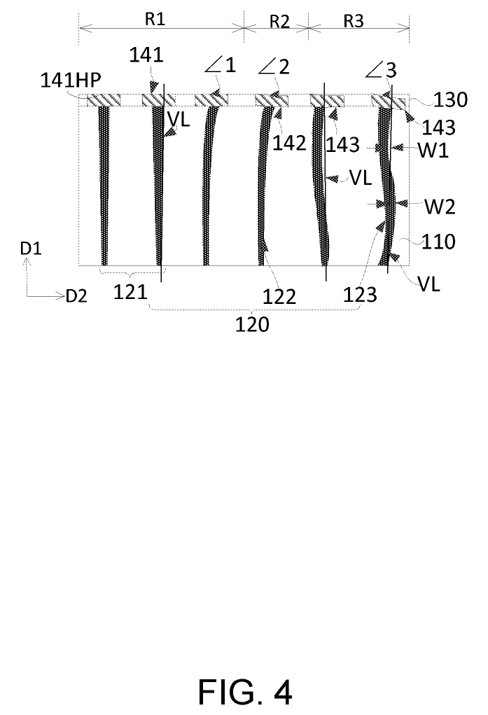

Please refer to FIGS. 3 and 4. FIG. 3 is a schematic cross-sectional view of a portion of a semiconductor structure in a second embodiment of the present application. FIG. 4 is a schematic diagram of an enlarged semiconductor structure corresponding to the black dashed box in FIG. 3 with auxiliary lines added. As shown in FIGS. 3 and 4, the semiconductor structure in the second embodiment of the present application is substantially the same as that in the above first embodiment. For example, it also includes a substrate 100, a plurality of plugs 120, a plurality of contact pads 140, a first dielectric layer 110 (with the first-layer plugs disposed therein), a second dielectric layer 130, a third dielectric layer 150 (with second-layer plugs 160 disposed therein), and a fourth dielectric layer 170. Where, the plurality of plugs 120 located in the same dielectric layer can also be divided into first plugs 121, second plugs 122, and third plugs 123 arranged from a central position to an edge position; and the third dielectric layer 130 on the top surfaces of the first plugs 121, the second plugs 122, and the third plugs 123 also has first contact pads 141, second contact pads 142, and third contact pads 143 physically contacting the top surfaces of the respective plugs 120 and having inclination angles. The same parts will not be repeated here. The main difference between the semiconductor structure of the second embodiment of the present application and the above first embodiment is that: each of some plugs 120 among the plurality of plugs 120 not only has the first portion or the recess part, but also has a second portion or a protruding part located on the lower half of the corresponding plug, so as to form a S shape. For ease of distinction, in the embodiment, a straight line connecting the topmost point and bottommost point of the single side surface of each plug is called a vertical line VL. Obviously, in the embodiment, among the plurality of plugs 120 located in the same dielectric layer, such as the first dielectric layer 110, some plugs can be S-shaped, some plugs can be C-shaped (same as the first embodiment above), and some plugs can be straight. For an S-shaped plug, such as the third plug 123 in FIG. 4, the recess part is located on its upper half or to the left side of the corresponding vertical line VL, and has a first offset W1 relative to this vertical line VL, while the protruding part of this third plug 123 is located on its lower half or to the right side of the corresponding vertical line VL, and has a second offset W2 (a second distance from the protruding part to the vertical line VL) relative to this vertical line VL. In one embodiment, for the same plug 120, the first offset W1 is greater than the corresponding second offset W2. For different plugs 120, from the central position to the edge position, such as from the first plugs 121 to the third plugs 123, the corresponding first offsets W1 or second offsets W2 both increase from the first area R1 to the third area R3. For example, the first offsets W1 of the first plugs 121 are less than those of the second plugs 122, the first offsets W1 of the second plugs 122 are less than those of the third plugs 123, and the second offsets W2 of the first plugs 121 are less than those of the second plugs 122, and the second offsets W2 of the second plugs 122 are less than those of the third plugs 123, but is not limited thereto.

In summary, the semiconductor structure includes a plurality of plugs and a plurality of contact pads, where the plurality of contact pads are respectively disposed on the plurality of plugs, and at least one contact pad has a top surface that is a horizontal plane extending parallel to the first direction, and top surfaces of at least two contact pads have different inclination angles relative to the horizontal plane, thereby proposing a new structure for semiconductor structures, and achieving the purpose of improving both the performance and reliability of semiconductor devices.

The above description is only the preferred embodiments of the present application and is not intended to limit the protection scope of the present application. Any modifications, equivalent replacements, improvements, etc., made within the spirit and principles of the present application shall be included within the protection scope of the present application.

What is claimed is:

1. A semiconductor structure, comprising:
a substrate;
a plurality of plugs, extending along a first direction and disposed on the substrate spaced apart from each other along a second direction perpendicular to the first direction; and
a plurality of contact pads, disposed on the plurality of plugs respectively, wherein at least one contact pad among the plurality of contact pads has a top surface that is a horizontal plane extending parallel to the second direction, and at least two contact pads among the plurality of contact pads have top surfaces having different inclination angles relative to the horizontal plane.

2. The semiconductor structure according to claim 1, wherein at least one plug among the plurality of plugs has a curved side surface, and the side surface has a recess.

3. The semiconductor structure according to claim 2, wherein the semiconductor structure further comprises:
a plurality of hypothetical auxiliary lines, each of which is defined by a straight line connecting a topmost point and a bottommost point of the side surface of the plugs; a maximum distance in the second direction from the recess of the side surface each of the plugs to the corresponding hypothetical auxiliary line is a first offset.

4. The semiconductor structure according to claim 3, wherein the first offsets between the plugs and the corresponding hypothetical auxiliary lines increase from a central position to an edge position.

5. The semiconductor structure according to claim 4, wherein the side surface of at least one plug further has a protruding part, and a maximum distance in the second direction from the protruding part to the corresponding hypothetical auxiliary line is a second offset.

6. The semiconductor structure according to claim 5, wherein for the same plug, the first offset is greater than the corresponding second offset.

7. The semiconductor structure according to claim 5, wherein the plurality of plugs comprises a first plug, a second plug, and a third plug arranged sequentially along the second direction from the central position to the edge position; and the first plug, the second plug, and the third plug physically contact a first contact pad, a second contact pad, and a third contact pad, respectively, wherein the first offsets and/or the second offsets of the first plug, the second plug, and the third plug progressively increase.

8. The semiconductor structure according to claim 7, wherein a top surface of the first contact pad is a horizontal plane extending parallel to the second direction, a top surface of the second contact pad has a first inclination angle relative to the horizontal plane, a top surface of the third contact pad has a second inclination angle relative to the horizontal plane; the second contact pad is located between the first contact pad and the third contact pad, and the first inclination angle is smaller than the second inclination angle.

9. The semiconductor structure according to claim 1, wherein the inclination angles of the top surfaces of the multiple contact pads relative to the horizontal plane increase from the central position to the edge position along the second direction.

10. The semiconductor structure according to claim 1, wherein a ratio of a height in the first direction to a width in the second direction of the plug is greater than 10.

11. The semiconductor structure according to claim 1, wherein the semiconductor structure further comprises:
dielectric layers between adjacent contact pads and between adjacent plugs.

12. The semiconductor structure according to claim 11, wherein the contact pad located at edge position among the plurality of contact pads do not have other plugs provided within the dielectric layer on the side opposite to other contact pads.

13. The semiconductor structure according to claim 2, wherein the semiconductor structure further comprises:
a plurality of hypothetical vertical lines, each of which is defined by a straight line passing through the bottommost point of the side surface of the plug and extending parallel to the first direction; the plug at least comprises a first portion and a second portion respectively located at two sides of the corresponding hypothetical vertical line.

14. A semiconductor structure, comprising:
a substrate;
a plurality of plugs, extending along a first direction and disposed on the substrate spaced apart from each other along a second direction perpendicular to the first direction; and
a plurality of hypothetical auxiliary lines, each of which is defined by a straight line connecting a topmost point and a bottommost point of a single side surface of the plug; the single side surface of at least one plug comprises a first portion and a second portion respectively bending toward two opposite sides of the hypothetical auxiliary line.

15. The semiconductor structure according to claim 14, wherein the semiconductor structure further comprises:
a plurality of contact pads, disposed on the substrate spaced apart from each other along the second direction, and each contact pad physically contacts each respective plug,
wherein, the contact pad located at an edge position among the plurality of contact pads has an inclination angle relative to a horizontal plane extending along the second direction is greater than inclination angles of other contact pads relative to the horizontal plane.

16. The semiconductor structure according to claim 14, wherein the first portion of the single side surface of the plug is located on an upper half of the plug and forms a recessed part, a maximum distance in the second direction from the first portion to the corresponding hypothetical auxiliary line is a first offset; wherein the first offsets between the plurality of plugs and the corresponding hypothetical auxiliary lines increase from a central position to an edge position.

17. The semiconductor structure according to claim 16, wherein the second portion of the single side surface of the plug is located on a lower half of the plug and forms a protruding part, and a maximum distance in the second direction from the second portion to the corresponding hypothetical auxiliary line is a second offset.

18. The semiconductor structure according to claim 17, wherein for the same plug, the first offset is greater than the corresponding second offset.

19. The semiconductor structure according to claim 14, wherein the inclination angles of the top surfaces of the plurality of contact pads relative to the horizontal plane increase from the central position to the edge position.

20. The semiconductor structure according to claim 14, wherein a ratio of a height in the first direction to a width in the second direction of the plug is greater than 10.
